(19) United States
(12) Patent Application Publication
(10) Pub. No.: US 2009/0256589 A1
(43) Pub. Date: Oct. 15, 2009

(54) PROGRAMMABLE DEVICE, ELECTRONIC DEVICE, AND METHOD FOR CONTROLLING PROGRAMMABLE DEVICE

(76) Inventors: Takashi Nakagawa, Tokyo (JP); Tetsuya Yatagai, Tokyo (JP); Hideki Ohwada, Tokyo (JP); Yoshio Takayanagi, Tokyo (JP); Tatsuya Higuchi, Tokyo (JP); Yuji Simoyama, Tokyo (JP); Tatsuya Nakano, Tokyo (JP); Tomohiro Nakano, Tokyo (JP); Naoto Yamamoto, Tokyo (JP); Atsushi Kato, Tokyo (JP)

Correspondence Address: NEC CORPORATION OF AMERICA, 6535 N. STATE HWY 161, IRVING, TX, 75039, US

(21) Appl. No.: 12/423,265

(22) Filed: Apr. 14, 2009

(30) Foreign Application Priority Data
Apr. 14, 2008 (JP) 2008-104546

(51) Int. Cl. H03K 19/173; H03K 19/177

(52) U.S. Cl. 326/38; 326/39

(57) ABSTRACT

A programmable device connected to a storage unit which stores logic circuit configuration information to form a logic circuit and control circuit configuration information to form a control circuit includes a first programmable logic device and a second programmable logic device, and a configuration unit which forms the control circuit in the first programmable logic device, by providing the control circuit configuration information in the storage unit to the first programmable logic device. The control circuit formed in the first programmable logic device forms the logic circuit in the second programmable logic device, by providing the logic circuit configuration information in the storage unit to the second programmable logic device.

This application is based upon and claims the benefit of priority from Japanese patent application No. 2008-104546, filed on Apr. 14, 2008, the disclosure of which is incorporated herein in its entirety by reference.

### BACKGROUND OF THE INVENTION

1. Field of the Invention

The present invention relates to a programmable device including a programmable logic device, such as an FPGA (Field Programmable Gate Array), an electronic device, and a method for controlling the programmable device.

2. Description of the Related Art

A programmable logic device, such as an FPGA, has been used as a component that makes up the circuitry of a digital circuit arrangement.

The internal circuit of an FPGA can be modified according to any circuit configuration information to form a logic circuit (configuration data) by reading (configuring) the circuit configuration information. In particular, the FPGA is useful in the case of designing a digital circuit such as a logic circuit, or the like, because the FPGA allows the circuit to be easily modified without having to remake the device.

Typically, the circuit configuration information of the FPGA is written in nonvolatile memory (flash memory) provided outside the FPGA.

Upon power activation, a configuration circuit in the FPGA converts the circuit configuration information in the flash memory into a volatile memory (e.g., SARAM) inside the FPGA. According to this circuit configuration information of the internal memory, a circuit is formed in the FPGA (i.e., the configuration is completed).

Accordingly, by rewriting the circuit configuration information in flash memory, the circuit implemented by the FPGA can be modified.

Therefore, the functional modification or enhancement of the circuit in the FPGA on hardware deployed in a field (for example, a site where an electronic device including the FPGA is arranged) can be accomplished by remotely rewriting (downloading) the circuit configuration information in flash memory.

Japanese Patent Laid-Open No. 2007-334538 discloses a programmable logic circuit arrangement including an FPGA, a memory, and an FPGA controller. The FPGA controller is a so-called configuration circuit and causes the FPGA to read the circuit configuration information in memory.

The FPGA controller described in Japanese Patent Laid-Open No. 2007-334538 is a circuit which performs only a specific operation preprogrammed in the FPGA controller. Thus, this FPGA controller causes the FPGA to read the circuit configuration information in the memory according to the preprogrammed specific operation.

In the programmable logic circuit arrangement described in Japanese Patent Laid-Open No. 2007-334538, the FPGA controller (configuration circuit) causes the FPGA to read the circuit configuration information in the memory according to the preprogrammed specific operation.

Therefore, for example, an electronic device including plural types of programmable logic circuit arrangements, that is, plural types of programmable logic circuit arrangements having FPGA controllers in which operations are different from each other are programmed, causes a problem as follows.

When functional modification or enhancement of the circuit formed in each FPGA in the electronic device is performed in the field, individual circuit configuration information needs to be written in each memory depending on the types of programmable logic circuit arrangements, more specifically, depending on the types of the FPGA controllers, because each FPGA controller has a different operation.

Thus, in the field, it is not possible to uniquely rewrite the circuit configuration information in each memory in order to perform functional modification or enhancement of the circuit formed in each FPGA in the electronic device.

Therefore, there has been a problem in which performing functional modification or enhancement of the circuit formed in each FPGA in the electronic device is not easy.

### SUMMARY OF THE INVENTION

An exemplary object of the present invention is to provide a programmable device, an electronic device, and a method for controlling the programmable device capable of solving the problem described above.

A programmable device, which is connected to a storage unit which stores logic circuit configuration information to form a logic circuit and control circuit configuration information to form a control circuit, according to an exemplary aspect of the invention includes:

a first programmable logic device and a second programmable logic device; and

a configuration unit which forms the control circuit in the first programmable logic device, by providing control circuit configuration information in the storage unit to the first programmable logic device, wherein

the control circuit formed in the first programmable logic device forms the logic circuit in the second programmable logic device, by providing logic circuit configuration information in the storage unit to the second programmable logic device.

An electronic device according to an exemplary aspect of the invention includes:

a storage unit which stores logic circuit configuration information to form a logic circuit and control circuit configuration information to form a control circuit;

a first programmable logic device and a second programmable logic device; and

a configuration unit which forms the control circuit in the first programmable logic device, by providing the control circuit configuration information in the storage unit to the first programmable logic device, wherein

the control circuit formed in the first programmable logic device forms the logic circuit in the second programmable logic device, by providing the logic circuit configuration information in the storage unit to the second programmable logic device.

A method for controlling a programmable device, which is performed by the programmable device connected to a storage unit which stores logic circuit configuration information to form a logic circuit and control circuit configuration information to form a control circuit, the programmable device comprising a first programmable logic device and a second programmable logic device, according to an exemplary aspect of the invention includes:

forming the control circuit in the first programmable logic device, by providing control circuit configuration information in the storage unit to the first programmable logic device; and

forming the logic circuit in the second programmable logic device, by providing the logic circuit configuration information in the storage unit to the second programmable logic device by the control circuit formed in the first programmable logic device.

A method for controlling a programmable device, which is performed by an electronic device comprising a storage unit which stores logic circuit configuration information to form a logic circuit and control circuit configuration information to form a control circuit, and a first programmable logic device and a second programmable logic device, according to an exemplary aspect of the invention includes:

forming the control circuit in the first programmable logic device, by providing the control circuit configuration information in the storage unit to the first programmable logic device; and

forming the logic circuit in the second programmable logic device, by providing the logic circuit configuration information in the storage unit to the second programmable logic device by using the control circuit formed in the first programmable logic device.

The above and other objects, features, and advantages of the present invention will become apparent from the following description with reference to the accompanying drawings which illustrate an example of the present invention.

### BRIEF DESCRIPTION OF THE DRAWINGS

FIG. 1 is a block diagram showing an electronic device having a programmable device according to a first exemplary embodiment;

FIG. 2A is an explanatory diagram showing FPGA circuit 101A;

FIG. 2B is an explanatory diagram showing FPGA circuit 101B;

FIG. 3 is an explanatory diagram showing a memory map of flash memory 102;

FIG. 4 is a flow chart for describing an operation of FPGA circuit 101; and

FIG. 5 is a timing flow chart for describing an operation according to a second exemplary embodiment.

### DETAILED DESCRIPTION OF EXEMPLARY EMBODIMENTS

Exemplary embodiments will now be described in detail with reference to the drawings.

### First Exemplary Embodiment

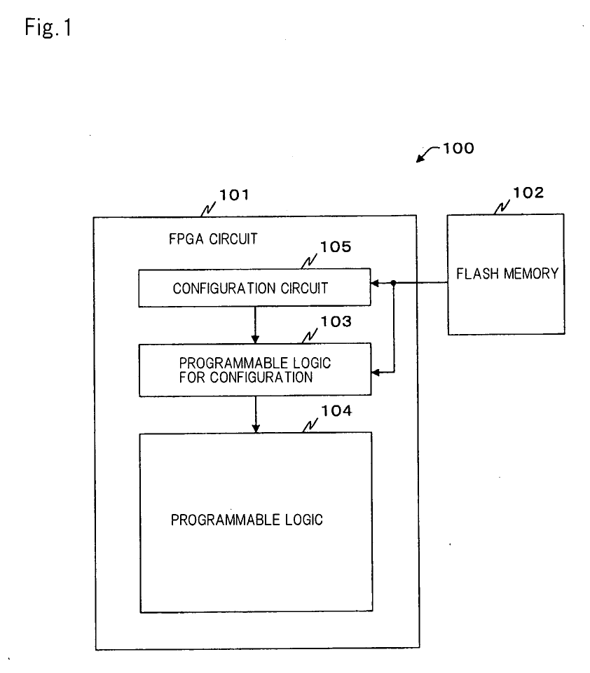

FIG. 1 is a block diagram showing an electronic device having a programmable device according to a first exemplary embodiment of the present invention.

In FIG. 1, electronic device 100 includes FPGA circuit 101 and flash memory 102. FPGA circuit 101 includes programmable logic for configuration 103, programmable logic 104, and configuration circuit 105.

Electronic device 100 is an electronic device in which functional modification or enhancement is likely to be performed, such as a wireless base station. Note that electronic device 100 is not limited to a wireless base station and can be different as appropriate.

Programmable logic for configuration 103 can be called a first programmable logic device. Programmable logic for configuration 103 is, for example, an FPGA, and forms any circuit when receiving any circuit configuration information (configuration data) to form the circuit.

Programmable logic 104 can be called a second programmable logic device. Programmable logic 104 is, for example, an FPGA, and forms any circuit when receiving any circuit configuration information to form the circuit.

Note that programmable logic for configuration 103 and programmable logic 104 can be any programmable logic devices other than FPGAs.

Flash memory 102 can be generally called storage means. Note that the storage means is preferably a rewritable nonvolatile memory. Flash memory 102 is an example of a rewritable nonvolatile memory and stores both logic circuit configuration information (configuration data) to form a logic circuit and control circuit configuration information (configuration data) to form a control circuit.

A logic circuit formed based on the logic circuit configuration information is a circuit to be implemented in programmable logic 104.

When a control circuit formed based on the control circuit configuration information is formed, for example, in programmable logic for configuration 103, the control circuit forms a logic circuit according to the logic circuit configuration information in programmable logic 104, by providing the logic circuit configuration information in flash memory 102 to programmable logic 104.

Configuration circuit 105 can be generally called configuration means. Configuration circuit 105 forms a control circuit according to the control circuit configuration information in programmable logic for configuration 103, by providing the control circuit configuration information in flash memory 102 to programmable logic for configuration 103.

A summary of the operation will now be described.

When FPGA circuit 101 is reset, configuration circuit 105 first reads out the control circuit configuration information from flash memory 102 and provides the control circuit configuration information to programmable logic for configuration 103.

Upon receiving the control circuit configuration information from configuration circuit 105, programmable logic for configuration 103 forms a control circuit based on the control circuit configuration information.

The control circuit formed in programmable logic for configuration 103 reads out the logic circuit configuration information from flash memory 102 using a reading technique based on the control circuit configuration information and provides the logic circuit configuration information to programmable logic 104.

Upon receiving the logic circuit configuration information from the control circuit formed in programmable logic for configuration 103, programmable logic 104 forms a logic circuit based on the logic circuit configuration information.

An exemplary operation will now be described in detail.

Hereinafter, assume that there are two types of FPGA circuits, 101A and 101B, as FPGA circuits 101 on hardware in an electronic device deployed in a field and that these two types of FPGA circuits 101A and 101B cannot share the logic circuit configuration information (configuration data).

Assume that FPGA circuit 101A can form a circuit (logic circuit) to be implemented by using configuration data (logic circuit configuration information) 102A. Also assume that FPGA circuit 101B can form a circuit (logic circuit) to be implemented by using configuration data (logic circuit configuration information) 102B.

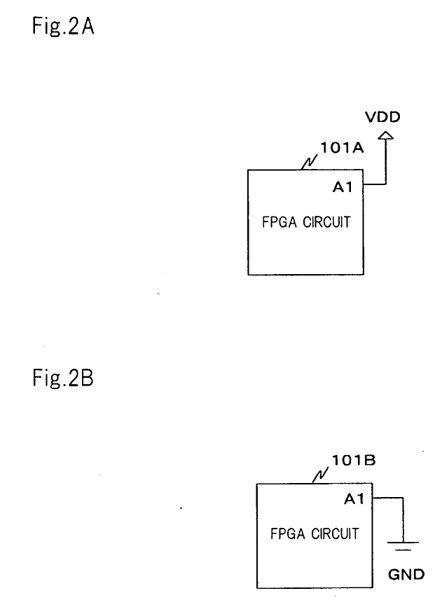

Further assume that, in advance, pin A1 of FPGA circuit 101A is fixed at the same level as the power supply voltage (VDD) and pin A1 of FPGA circuit 101B is grounded (GND), as shown in FIG. 2A and FIG. 2B.

Pin A1 can be generally called input means. The power supply voltage (VDD) and the ground (GND) inputted to each pin A1 can be generally called setting information. Note that the input means is not limited to pin A1 and can be different. Also the setting information is not limited to the power supply voltage (VDD) and the ground (GND) and can be different as appropriate.

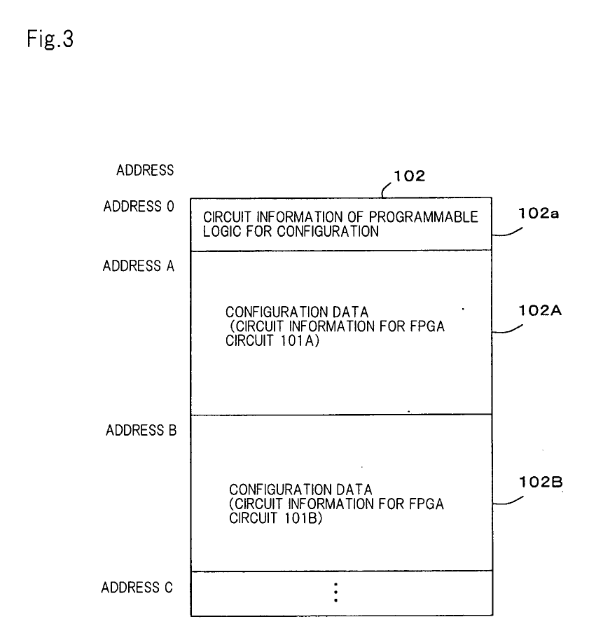

FIG. 3 is an explanatory diagram showing a memory map of flash memory 102.

In FIG. 3, flash memory 102 stores circuit configuration information of programmable logic for configuration 102a which is control circuit configuration information and configuration data 102A and 102B which are plural types of logic circuit configuration information.

In the present exemplary embodiment, circuit configuration information of programmable logic for configuration 102a is stored between address 0 (starting address) and an address immediately before address A in flash memory 102. Configuration data 102A is stored between address A and an address immediately before address B in flash memory 102. Configuration data 102B is stored between address B and an address immediately before address C in flash memory 102.

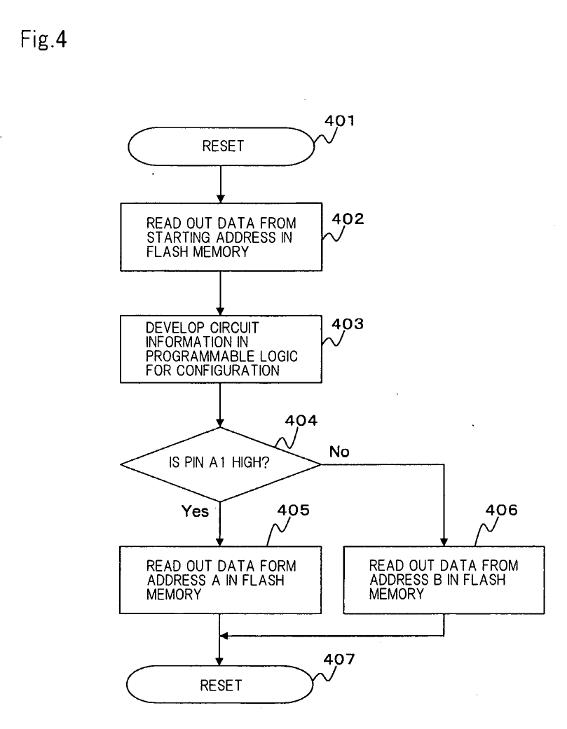

FIG. 4 is a flow chart for describing an operation of FPGA circuit 101.

Hereinafter, a configuration operation of FPGA circuit 101 in the above assumption will be described using FIG. 1 and FIG. 4.

In order to perform the functional enhancement of FPGA circuit 101 on hardware in the electronic device deployed in the field, assume that data (logic circuit configuration information and control circuit configuration information) in flash memory 102 is rewritten using the format shown in FIG. 3.

After rewriting data in flash memory 102, FPGA circuit 101 is reset (step 401).

Upon resetting FPGA circuit 101, configuration circuit 105 reads out data from the starting address in flash memory 102 (step 402).

Having completed reading out circuit configuration information of programmable logic for configuration (hereinafter, simply referred to as “circuit configuration information”) 102a from flash memory 102, configuration circuit 105 develops circuit configuration information 102a in programmable logic for configuration 103 (step 403).

Upon receiving circuit configuration information 102a, programmable logic for configuration 103 implements a configuration according to circuit configuration information 102a given, and forms a control circuit which determines the starting address in reading data from flash memory 102 for the next time based on the electronic level of pin A1 of FPGA circuit 101.

Note that determining the starting address in reading data from flash memory 102 means selecting specific logic circuit configuration information from plural types of configuration data (logic circuit configuration information) 102A and 102B.

The control circuit formed in programmable logic for configuration 103 reads out configuration data (specific logic circuit configuration information) corresponding to the circuit to be formed in programmable logic 104 from address A in flash memory 102 when the electric level of pin A1 is High, and reads out the same from address B in flash memory 102 when the electric level of pin A1 is Low (step 404 to step 406).

Having completed reading of given configuration data (specific logic circuit configuration information), the control circuit formed in programmable logic for configuration 103 develops the configuration data in programmable logic 104. Programmable logic 104 forms a logic circuit according to the configuration data and completes the configuration (step 407).

The advantage of the present exemplary embodiment will now be described.

According to the present exemplary embodiment, configuration circuit 105 forms the control circuit in programmable logic for configuration 103, by providing the control circuit configuration information in flash memory 102 to programmable logic 103 for configuration.

The control circuit formed in programmable logic 103 for configuration forms a logic circuit according to the logic circuit configuration information in programmable logic 104, by providing the logic circuit configuration information in flash memory 102 to programmable logic 104.

Accordingly, by modifying the control circuit configuration information in flash memory 102, the formation of the control circuit in programmable logic 103 for configuration can be customized.

Thus, when the functional modification or enhancement of the logic circuit formed in programmable logic 104 is performed, for example, the control circuit can be customized so that the control circuit reads the logic circuit configuration information to perform the functional modification or enhancement of the logic circuit from flash memory 102 to provide the logic circuit configuration information to programmable logic 104.

Therefore, functional modification or enhancement of the circuit formed in programmable logic 104 can be easily performed.

In addition, since the configuration process can also be changed, in an electronic device having a plurality of FPGA circuits 101 in which logic circuits that are different from each other are formed, functional modification or enhancement of all logic circuits formed in the plurality of FPGA circuits 101 in the electronic device can be easily performed by uniquely rewriting the configuration data in each flash memory 102.

More specifically, it is possible to write identical circuit configuration information (configuration data) into each flash memory 102 without depending on the types of FPGA circuits 101. Accordingly, functional enhancement or modification of the circuit in each FPGA circuit 101 in the electronic device deployed in the field can be easily performed.

In the present exemplary embodiment, control circuit configuration information is information to form the control circuit which selects specific logic circuit configuration information from plural types of logic circuit configuration information based on the setting information received by pin A1, and which provides the specific logic circuit configuration information to programmable logic 104.

In this case, for example, when the electric level of a specific terminal is detected as High, the control circuit formed in programmable logic 103 for configuration can read out the corresponding circuit configuration information from flash memory 102 which holds plural types of circuit configuration information, by operating to read out data from the specific address in flash memory 102.

### Second Exemplary Embodiment

A second exemplary embodiment will now be described.

In FIG. 3 and FIG. 4, a description of an example has been made assuming that FPGA circuit 101 and flash memory 102 are connected with a parallel bus. In the second exemplary embodiment, a case where FPGA circuit 101 and flash memory 102 are serially connected will be described. Note that the basic arrangement of FPGA circuit 101 in the second exemplary embodiment is the same as that shown in FIG. 1.

When flash memory 102 is a serial flash memory, configuration circuit 105 sequentially reads out data from flash memory 102 and develops the circuit configuration information in programmable logic 103 for configuration.

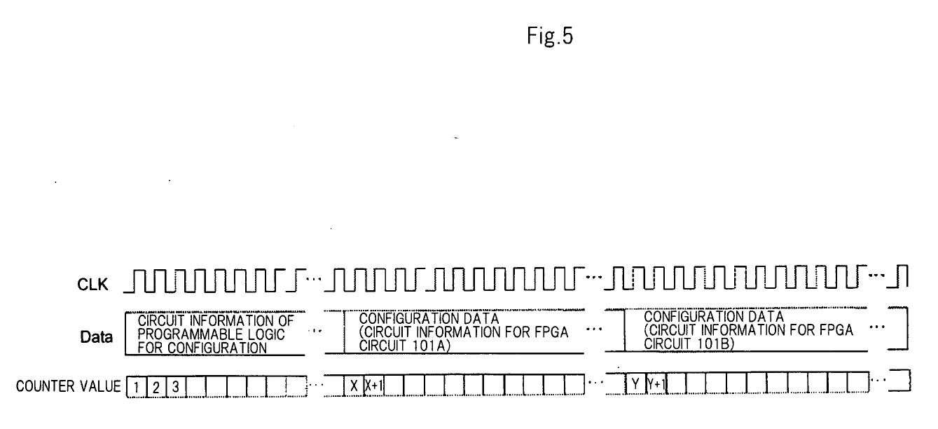

The control circuit formed in programmable logic for configuration 103 has a counter. As shown in FIG. 5, the control circuit operates so that data is developed in programmable logic 104 when the counter value becomes X for FPGA circuit 101A, and when the counter value becomes Y for FPGA circuit 101B, thereby completing the configuration with different pieces of circuit configuration information for FPGA circuits 101A and 101B, respectively.

In each exemplary embodiment described above, the arrangement illustrated is only an example and the present invention is not limited thereto.

The description has been made assuming that two types of FPGA circuits are configured in each exemplary embodiment; however, for example, the number of types of FPGA circuits is not limited to two and can be appropriately changed, and plural types of FPGA circuits can be configured with different pieces of circuit configuration information, respectively.

An exemplary advantage of the present invention is that functional modification or enhancement of the circuit formed in the programmable logic device can be easily performed.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A programmable device connected to a storage unit which stores logic circuit configuration information to form a logic circuit and control circuit configuration information to form a control circuit, the programmable device comprising:
a first programmable logic device and a second programmable logic device; and
a configuration unit which forms the control circuit in the first programmable logic device, by providing the control circuit configuration information in the storage unit to the first programmable logic device, wherein
the control circuit formed in the first programmable logic device forms the logic circuit in the second programmable logic device, by providing the logic circuit configuration information in the storage unit to the second programmable logic device.

2. The programmable device according to claim 1, wherein
the storage unit stores plural types of the logic circuit configuration information,
the programmable device further comprises an input unit which receives setting information, and
the control circuit formed in the first programmable logic device forms a logic circuit according to specific logic circuit configuration information in the second programmable logic device, by selecting the specific logic circuit configuration information from the plural types of logic circuit configuration information in the storage unit based on the setting information received by the input unit, and by providing the specific logic circuit configuration information to the second programmable logic device.

3. The programmable device according to claim 1, wherein the first programmable logic device and the second programmable logic device are FPGAs.

4. An electronic device comprising:
a storage unit which stores logic circuit configuration information to form a logic circuit and control circuit configuration information to form a control circuit;
a first programmable logic device and a second programmable logic device; and
a configuration unit which forms the control circuit in the first programmable logic device, by providing the control circuit configuration information in the storage unit to the first programmable logic device, wherein
the control circuit formed in the first programmable logic device forms the logic circuit in the second programmable logic device, by providing the logic circuit configuration information in the storage unit to the second programmable logic device.

5. The electronic device according to claim 4, further comprising an input unit which receives setting information, wherein
the storage unit stores plural types of the logic circuit configuration information, and
the control circuit formed in the first programmable logic device forms a logic circuit according to specific logic circuit configuration information in the second programmable logic device, by selecting the specific logic circuit configuration information from the plural types of the logic circuit configuration information in the storage unit based on the setting information received by the input unit, and by providing the specific logic circuit configuration information to the second programmable logic device.

6. The electronic device according to claim 4, wherein the first programmable logic device and the second programmable logic device are FPGAs.

7. A method for controlling a programmable device, performed by the programmable device connected to a storage unit which stores logic circuit configuration information to form a logic circuit and control circuit configuration information to form a control circuit, the programmable device comprising a first programmable logic device and a second programmable logic device, the method comprising:
forming the control circuit in the first programmable logic device, by providing the control circuit configuration information in the storage unit to the first programmable logic device; and
forming the logic circuit in the second programmable logic device, by providing the logic circuit configuration information in the storage unit to the second programmable logic device by using the control circuit formed in the first programmable logic device.

8. The method for controlling the programmable device according to claim 7, wherein
the storage unit stores plural types of the logic circuit configuration information,
the method further comprises receiving setting information, and
the forming of the logic circuit comprises forming a logic circuit according to specific logic circuit configuration information in the second programmable logic device, by selecting the specific logic circuit configuration information from the plural types of logic circuit configuration information in the storage unit based on the received setting information, and by providing the specific logic circuit configuration information to the second programmable logic device, by using the control circuit formed in the first programmable logic device.

9. A method for controlling a programmable device, performed by an electronic device comprising a storage unit which stores logic circuit configuration information to form a logic circuit and control circuit configuration information to form a control circuit, and a first programmable logic device and a second programmable logic device, the method comprising:
forming the control circuit in the first programmable logic device, by providing the control circuit configuration information in the storage unit to the first programmable logic device; and
forming the logic circuit in the second programmable logic device, by providing the logic circuit configuration information in the storage unit to the second programmable logic device by using the control circuit formed in the first programmable logic device.

10. The method for controlling the programmable device according to claim 9, wherein
the storing unit stores plural types of the logic circuit configuration information,
the method further comprises receiving setting information, and
in the forming of the logic circuit, the control circuit formed in the first programmable logic device forms a logic circuit according to specific logic circuit configuration information in the second programmable logic device, by selecting the specific logic circuit configuration information from the plural types of logic circuit configuration information in the storage unit based on the received setting information, and by providing the specific logic circuit configuration information to the second programmable logic device.

11. A programmable device connected to storage means for storing logic circuit configuration information to form a logic circuit and control circuit configuration information to form a control circuit, the programmable device comprising:
a first programmable logic device and a second programmable logic device; and
configuration means for forming the control circuit in the first programmable logic device, by providing the control circuit configuration information in the storage means to the first programmable logic device, wherein
the control circuit formed in the first programmable logic device forms the logic circuit in the second programmable logic device, by providing the logic circuit configuration information in the storage means to the second programmable logic device.

12. An electronic device comprising:
storage means for storing logic circuit configuration information to form a logic circuit and control circuit configuration information to form a control circuit;
a first programmable logic device and a second programmable logic device; and
configuration means for forming the control circuit in the first programmable logic device, by providing the control circuit configuration information in the storage means to the first programmable logic device, wherein
the control circuit formed in the first programmable logic device forms the logic circuit in the second programmable logic device, by providing the logic circuit configuration information in the storage means to the second programmable logic device.
